(19) United States
(12) Patent Application Publication
(10) Pub. No.: US 2026/0328873 A1
(43) Pub. Date: Oct. 22, 2026

(54) AN INITIALISATION DEVICE

(71) Applicant: Analog Devices International Unlimited Company, Limerick (IE)

(72) Inventors: Jochen Schmitt, Biedenkopf (DE); Enno Lage, Kiel (DE); Monsoon Dutt, London (GB); Stephen A. Bradshaw, Hungerford (GB); Bryan Patricio Aguiar Gonzalez, London (GB)

(21) Appl. No.: 19/730,366

(22) Filed: Jul. 2, 2026

Related U.S. Application Data
(63) Continuation of application No. 18/265,133, filed on Dec. 7, 2021.

(30) Foreign Application Priority Data
Dec. 10, 2020 (DE) 10 2020 132 914.8

(51) Int. Cl. G01R 33/12; G01D 5/14; G01R 33/00; G01R 33/09

(52) U.S. Cl. CPC G01R 33/1292; G01D 5/145; G01R 33/0017; G01R 33/091; G01D 2205/26

(57) ABSTRACT

The present disclosure provides a device for initializing a multi-turn sensor that initializes the sensor almost instantaneously, thereby consuming very little energy. The initialisation device is provided in the form of a conductor that is placed a small distance above or below the sensor spiral, the conductor being configured so that it crosses at least two opposing corners of the spiral. A sequence of current pulses is then applied to the conductor, wherein each current pulse is applied to a different part of the conductor such that a magnetic field is generated by the conductor to thereby generate pairs of domain walls in the magnetoresistive elements defining at least one corner region of spiral. Once the domain walls have been nucleated, the external magnetic field will drive the pairs of domain walls away from each other towards the adjacent corners, changing the magnetic alignment of the tracks as they pass through. As such, the spiral can be initialised very quickly by applying a current to the conductor in the correct direction.

### CLAIM OF PRIORITY

This application is a continuation of U.S. Non-Provisional application Ser. No. 18/265,133, filed Jun. 2, 2023, which is U.S. National Stage of PCT Application No. PCT/EP/2021/084515, filed Dec. 7, 2021, and published as WO 2022/122700 A1 on Jun. 16, 2022, which claims priority to DE Application No. 10 2020 132 914.8, filed Dec. 10, 2020, which is hereby incorporated by reference herein in their entirety.

### FIELD OF DISCLOSURE

The present disclosure relates to a device for initialising a multi-turn sensor and method of use. In particular, the present disclosure relates to an initialisation device configured to cause domain wall nucleation in the magnetoresistive track of the multi-turn sensor.

### BACKGROUND

Magnetic sensing devices comprising multi-turn sensors are commonly used in applications where there is a need to monitor the number of times a device has been turned. An example is a steering wheel in a vehicle.

Magnetic multi-turn (MT) sensors typically include magnetoresistive elements that are sensitive to an applied external magnetic field. The resistance of the magnetoresistive elements can be changed by rotating a magnetic field within the vicinity of the sensor. Variations in the resistance of the magnetoresistive elements will be tracked to determine the number of turns in the magnetic fields, which can be translated to a number of turns in the device being monitored. Typically, multi-turn sensors comprise a plurality of magnetoresistive elements laid out as a strip in an open loop spiral or closed loop spiral. Domain walls are caused to propagate around the spiral in response to rotations of an external magnetic field, causing the magnetic alignment of each element to change as it propagates through, which causes a corresponding change in resistance.

The magnetic turn count information stored in the sensor needs to match the physical turn count of the device the sensor is monitoring, and so the sensor must first be set in a known magnetic state before it can be used. The magnetoresistive elements therefore need to be magnetically initialised into one of two states, such that all the sensor outputs will be the same at either the start point of the mechanical system (i.e. zero turns of the magnetic field) or the end point (i.e. the maximum number of turns that the sensor can count), for example, all having either a “high” reading or a “low reading”. This is called the initialization state.

### SUMMARY OF DISCLOSURE

The present disclosure provides a device for initializing a multi-turn sensor that initializes the sensor almost instantaneously, thereby consuming very little energy. The initialisation device is provided in the form of a conductor that is placed a small distance above or below the sensor spiral, the conductor being configured so that it crosses at least two opposing corners of the spiral. A current is then applied to the conductor to generate a magnetic field in the corner sections of the spiral to nucleate domain walls. Once the domain walls have been nucleated, the external magnetic field will drive the pairs of domain walls away from each other towards the adjacent corners, changing the magnetic alignment of the tracks as they pass through into an initialised state. As such, the spiral can be initialised very quickly by applying a current to the conductor in the correct direction.

Accordingly, a first aspect of the present disclosure provides a device for initialising a magnetic multi-turn sensor, the multi-turn sensor having a plurality of magnetoresistive sensing elements connected in series and arranged in at least one spiral configuration having a plurality of corner regions, the device comprising:
a conductor arranged to be placed in proximity to the multi-turn sensor, wherein the conductor is configured to generate a magnetic field when a current pulse is applied to a predetermined part of the conductor, such that pairs of domain walls are generated in the magnetoresistive elements defining at least one corner region of the at least one spiral;
wherein the predetermined part of the conductor to which the current pulse is applied is selected based on a direction of an external magnetic field in proximity to the multi-turn sensor.

Once the multi-turn sensor has been installed in a mechanical system, the initialisation device can thus be used to quickly initialise the sensor by simply applying a current pulse to one part of conductor, thereby reducing the time and energy required to initialise the sensor. In this respect, once a current pulse has been applied and domain wall pairs generated, the external magnetic field in proximity to the sensor, for example, that of the mechanical system being monitored, will automatically propagate the domain walls around the spiral, thereby magnetising the magnetoresistive elements into the initialised state. The direction of the external magnetic field will determine dictate which direction the domain walls propagate. If the magnetic field causes the domain wall pairs to propagate towards each other, they will annihilate and the initialisation will not be completed. Therefore, the part of the conductor to which the current is applied, and thus the corner region in which the domain walls are generated, must be selected for the given direction of the external magnetic field to ensure the domain walls propagate away from each other.

The pre-determined part of the conductor is preferably a part located in proximity to a corner region of the at least one spiral. As such, when the current pulse is applied to that part, domain wall pairs are generated in the corresponding corner region.

More specifically, the conductor may extend from a first corner region of the at least one spiral to a second corner region of the at least one spiral, wherein the first and second corner regions are opposing corner regions. The conductor may further extend from a third corner of the at least one spiral to a fourth corner of the at least one spiral, wherein the third and fourth corner regions are opposing corner regions. As such, domain wall pairs may be generated in a pair of opposing corners of the sensor spiral by applying a current pulse to the part of the conductor extending between those two opposing corner regions. In this respect, the part of the conductor to be selected and the direction of the current will depend on which quadrant the magnetic field angle of the external magnetic field is in.

The conductor may comprise a plurality of terminals, the pre-determined part being one of the plurality of terminals. That is to say, the conductor may have terminals at each corner region. The initialisation device may also comprise a power supply connected to the plurality of terminals for supplying the current to the conductor.

The conductor may be cross-shaped. In such arrangements, each arm of the cross will be arranged over one corner region of the spiral.

The conductor preferably comprises a non-ferromagnetic material. For example, the non-ferromagnetic material may comprise one of. Gold and Aluminium.

A further aspect of the present disclosure provides a method of initialising a magnetic multi-turn sensor, the multi-turn sensor having a plurality of magnetoresistive sensing elements connected in series and arranged in at least one spiral configuration having a plurality of corner regions, the method comprising:
measuring a direction of an external magnetic field in proximity to the multi-turn sensor; and
applying a current pulse to a predetermined part of a conductor placed in proximity to the multi-turn sensor such that a further magnetic field is generated by the conductor, and such that pairs of domain walls are generated in the magnetoresistive elements defining at least one corner region of the at least one spiral;
wherein the predetermined part to which the current pulse is applied is dependent on the measured direction of the external magnetic field.

In some arrangements, the conductor extends between at least two opposing corner regions of the at least one spiral, the predetermined part being one of a first part located in proximity to a first corner region or a second part located in proximity to a second opposing corner region.

The current pulse is then applied between the first and second parts in dependence on the measured direction of the external magnetic field. That is to say, the direction in which the current is applied between these two parts will depend on the direction of the external magnetic field.

In such cases, the current pulse may be applied from the first part to the second part when a magnetic field angle of the external magnetic field is within a first half of a polar coordinate system, and from the second part to the first part when the magnetic field angle of the external magnetic field is within a second half of the polar coordinate system. For example, the current may be applied from the first to the second part when the magnetic field angle is between 0° and 180°, whilst the current is applied from the second to the first part when the magnetic field angle is between 180° and 360°.

The conductor may further extend between a third corner region and a fourth opposing corner region of the at least one spiral, the predetermined part further being one of a third part located in proximity to the third corner region or a fourth part located in proximity to the fourth corner region.

In such cases, the current pulse is further applied between the third and fourth parts in dependence on the measured direction of the external magnetic field. As before, the direction in in which the current is applied between these two parts will also depend on the direction of the external magnetic field.

For example, in cases where the conductor comprises four parts arranged over four respective corner regions, the current pulse is applied:
(i) from the first part to the second part when a magnetic field angle of the external magnetic field is within a first quadrant of a polar coordinate system (e.g. 0° to 90°),
(ii) from the second part to the first part when the magnetic field angle of the external magnetic field is within a second quadrant of the polar coordinate system (e.g. 180° to 270°);
(iii) from the third part to the fourth part when the magnetic field angle of the external magnetic field is within a third quadrant of the polar coordinate system (e.g. 90° to 180°); and
(iv) from the fourth part to the third part when the magnetic field angle of the external magnetic field is within a fourth quadrant of the polar coordinate system (e.g. 270° to 360°).

The direction of the external magnetic field is preferably measured using an angle sensor. In this respect, the angle senor may be a quadrant detector, or an angle sensor providing 360° absolute angle information. Alternatively, an angle sensor providing 180° absolute angle information may be used in conjunction with a quadrant detector.

A further aspect of the present disclosure provides a magnetic sensing system, comprising:
a multi-turn sensor having a plurality of magnetoresistive sensing elements connected in series and arranged in at least one spiral configuration having a plurality of corner regions;
an initialisation device comprising a conductor placed in proximity to the multi-turn sensor, wherein the conductor is configured to generate a magnetic field when a current pulse is applied to a predetermined part of the conductor, such that pairs of domain walls are generated in the magnetoresistive elements defining at least one corner region of the at least one spiral;
wherein the predetermined part of the conductor to which current pulse is applied is selected based on a direction of an external magnetic field in proximity to the multi-turn sensor.

The pre-determined part of the conductor is preferably a part located in proximity to a corner region of the at least one spiral. In this respect, the conductor may be placed a first distance above or below the multi-turn sensor. For example, the first distance may be about 2 micrometres up to about 8 micrometres.

The system may further comprise an angle sensor configured to measure the direction of the external magnetic field. In this respect, the angle senor may be a quadrant detector, or an angle sensor providing 360° absolute angle information. Alternatively, an angle sensor providing 180° absolute angle information may be used in conjunction with a quadrant detector. For example, the angle sensor may be one of: an anisotropic magnetoresistive (AMR) based single turn sensor, a giant magnetoresistive (GMR) based single turn sensor, a tunnel magnetoresistive (TMR) based single turn sensor, a Hall effect sensor and an inductive sensor.

The system may further comprise a processing circuit in communication with the multi-turn sensor, the angle sensor and the initialisation device. The processing device may be configured to control a power supply to input the current pulse to the predetermined part of the conductor. In this respect, the processing device may be configured to receive a signal from the angle sensor indicative of the direction of the external magnetic field, process the received signal to determine the predetermined part of the conductor, and control the power supply in dependence thereon.

The conductor may extend from a first corner region of the at least one spiral to a second corner region of the at least spiral, wherein the first and second corner regions are opposing corner regions.

The conductor may further extend from a third corner of the at least one spiral to a fourth corner of the at least one spiral, wherein the third and fourth corner regions are opposing corner regions.

In some arrangements, the plurality of magnetoresistive sensing elements may be arranged as two connected spirals, the initialisation device being arranged such that the conductor is located in proximity to at least two opposing corner regions of each spiral.

The system may further comprise a reference system, the reference system comprising a plurality of reference magnetoresistive sensing elements and a second initialisation device, the second initialisation device comprising a further conductor located in proximity to the plurality of reference magnetoresistive sensing elements. As such, the above concept may be extended to any reference resistors used in conjunction with the multi-turn sensor.

The magnetic multi-turn sensor may be a giant magnetoresistive (GMR) based multi-turn sensor, or a tunnel magnetoresistive (TMR) based multi-turn sensor. The plurality of magnetoresistive elements may also be arranged in an open loop or closed loop configuration.

The conductor of the first initialisation device preferably comprises a non-ferromagnetic material. For example, the non-ferromagnetic material may comprise one of. Gold, Copper, Aluminium and an alloy comprising Aluminium and Copper.

The system may be arranged on a first integrated circuit board. That is to say, the whole system may be provided in a single sensor package for installation on a mechanical system.

Yet a further aspect of the present disclosure provides a method of initialising a magnetic multi-turn sensor, the multi-turn sensor having a plurality of magnetoresistive sensing elements connected in series and arranged in at least one spiral configuration having a plurality of corner regions, the method comprising:
applying a sequence of current pulses to a conductor placed in proximity to the multi-turn sensor, wherein each current pulse is applied to a different part of the conductor such that a magnetic field is generated by the conductor to thereby generate pairs of domain walls in the magnetoresistive elements defining at least one corner region of the at least one spiral.

As such, a sequence of current pulses is applied to different parts of the conductor so that domain wall pairs are nucleated in multiple corner regions. Depending on the direction of an external magnetic field in proximity to the sensor, for example, generated by a magnet of the mechanical system in which the sensor is installed, the domain wall pairs will either propagate towards each other and annihilate, or propagate away from each other to thereby magnetise the magnetoresistive tracks into the initialised state. As such, at least one current pulse in the sequence will result in the sensor becoming initialised.

In some arrangements, the conductor extends between at least two opposing corner regions of the at least one spiral, with the current being applied in sequence between the two corner regions in both directions. In other arrangements, the conductor may further extend between a third corner region and a fourth opposing corner region of the at least one spiral, with the current being applied between each pair of opposing corner regions in both directions.

### BRIEF DESCRIPTION OF THE DRAWINGS

The present disclosure will now be described by way of example only with reference to the accompanying drawings in which:

FIG. 1 is an example of a magnetic multi-turn system comprising magnetoresistive elements in accordance with embodiments of the disclosure;

FIG. 2A is an example of a magnetic multi-turn sensor system in accordance with embodiments of the disclosure;

FIG. 2B is a graph for illustrating how the multi-turn sensor system of FIG. 2A is implemented;

FIGS. 3A-3B illustrate a method of initialisation in accordance with embodiments of the disclosure;

FIG. 4 further illustrates the method of initialisation in accordance with embodiments of the disclosure;

FIG. 5 is a further example multi-turn sensor system in accordance with embodiments of the disclosure;

FIG. 6A is a further example of a magnetic multi-turn sensor system in accordance with embodiments of the disclosure;

FIG. 6B is a graph for illustrating how the multi-turn sensor system of FIG. 6A is implemented;

FIG. 7 is a further example multi-turn sensor system in accordance with embodiments of the disclosure;

FIG. 8 illustrates a reference resistor for use with embodiments of the disclosure;

FIG. 9 is a schematic top view of a magnetic sensing device in accordance with an embodiment of the disclosure;

FIGS. 10A-B illustrate the magnetic layers in a GMR stack used in a multi-turn sensor in accordance with embodiments of the disclosure;

FIG. 11 illustrates the possible initialisation states in accordance with embodiments of the disclosure.

### DETAILED DESCRIPTION

Magnetic multi-turn sensors can be used to monitor the turn count of a rotating shaft. To do this, a magnet is typically mounted to the end of the rotating shaft, the multi-turn sensor being sensitive to the rotation of the magnetic field as the magnet rotates with the shaft. Such magnetic sensing can be applied to a variety of different applications, such as automotive applications, medical applications, industrial control applications, consumer applications, and a host of other applications which require information regarding a position of a rotating component.

For counting the number of turns, an xMR multi-turn sensor, typically, giant magnetoresistive or tunnel magnetoresistive, based on domain wall propagation in an open or closed loop spiral is used.

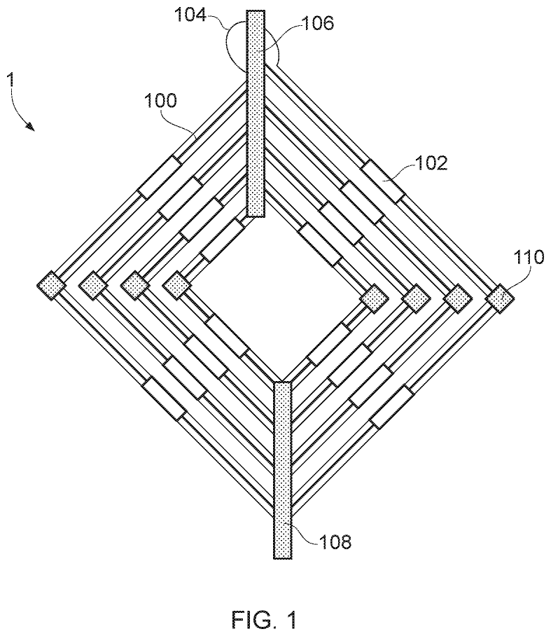

FIG. 1 shows an example of a magnetic strip layout representation of a magnetic multi-turn sensor 1 comprising a plurality of magnetoresistive elements 100 in accordance with the embodiments of the present disclosure. In the example of FIG. 1, the magnetic strip 100 is a giant magnetoresistance (GMR) track that is physically laid out in an open loop spiral configuration, although it will be appreciated that the sensor may also be formed from tunnel magnetoresistive (TMR) material. As such, the magnetic strip 100 has a plurality of segments formed of the magnetoresistive elements 102 arranged in series with each other. The magnetoresistive elements 102 act as variable resistors that change resistance in response to a magnetic alignment state. One end of the magnetic strip 100 is coupled to a domain wall generator (DWG) 104. In this respect, it will be appreciated that the DWG 104 may be coupled to either end of the magnetic strip 100. The DWG 104 generates domain walls in response to rotations in an external magnetic field, or the application of some other strong external magnetic field beyond the operating magnetic window of the sensor 1. These domain walls can then be injected into the magnetic strip 100. As the magnetic domain changes, the resistance of the GMR elements 102 will also change due to the resulting change in magnetic alignment.

In order to measure the varying resistance of the GMR elements 102 as domain walls are generated, the magnetic strip 100 is electrically connected to a supply voltage VDD 106 and to ground GND 108 to apply a voltage between a pair of opposite corners. The corners half way between the voltage supplies are provided with electrical connections 110 so as to provide half-bridge outputs. As such, the multi-turn sensor 1 comprises multiple Wheatstone bridge circuits, with each half-bridge 110 corresponding to one half-turn or 180° rotation of an external magnetic field. Measurements of voltage at the electrical connections 110 can thus be used to measure changes in the resistance of the GMR elements 102, which is indicative of changes in the magnetic alignment of the free layer.

The example shown by FIG. 1 comprises four spiral windings eight half-bridges 110, and is thus configured to count four turns of an external magnetic field. However, it will be appreciated that a multi-turn sensor may have any number of spiral windings depending on the number of GMR elements. In general, multi-turn sensors can count as many turns as spiral windings. It will also be appreciated that the GMR elements 102 may be electrically connected in any suitable way so as to provide sensor outputs representative of the changes in magnetic alignment state. For example, the GMR elements 102 may be connected in a matrix arrangement such as that described in US 2017/0261345, which is hereby incorporated by reference in its entirety. As a further alternative, each magnetoresistive element 102 may be connected individually, rather than in a bridge arrangement.

As described above, the magnetic turn count information stored in the sensor 1 needs to match the physical turn count of the device the sensor is monitoring, and so the sensor 1 must first be set in a known magnetic state before it can be used. To initialise the MT sensor, the mechanical system needs to be driven to either the start or end position, and the sensor spiral filled with domain walls such that the GMR elements 102 all provide the same sensor outputs. Typically, this is done by applying a very strong rotating magnetic field until initialisation has occurred, however, this method takes time and is thus energy intensive. Furthermore, the initialisation has to be carried out once the magnetic sensing system has been assembled and installed in the mechanical system. However, in many cases, there is not enough space to bring a magnet or electromagnet in close proximity in order to initialise the device once it is assembled.

The present disclosure therefore provides a device for initializing a multi-turn sensor that initializes the sensor almost instantaneously, thereby consuming very little energy. The initialisation device is provided in the form of a conductor that is placed a small distance above or below the MT sensor, the conductor being configured so that it crosses at least two opposing corners of the spiral. A current is then applied to the conductor to generate a magnetic field in the corner sections of the spiral to nucleate domain walls. Once the domain walls have been nucleated, the external magnetic field will drive the pairs of domain walls away from each other towards the adjacent corners, changing the magnetic alignment of the tracks as they pass through. As such, the spiral can be initialised very quickly by applying a current to the conductor in the correct direction.

The direction in which the current is applied will depend on the direction of an external magnetic field, typically, the magnetic field generated by the magnet that the sensor is going to be measuring. This is because the external magnetic field will drive the nucleated domain walls along the resistor tracks to get the required magnetisation. If the magnetic field is pointing in the wrong direction for the direction in which the current is applied, the nucleated domains walls will propagate towards each other and will annihilate.

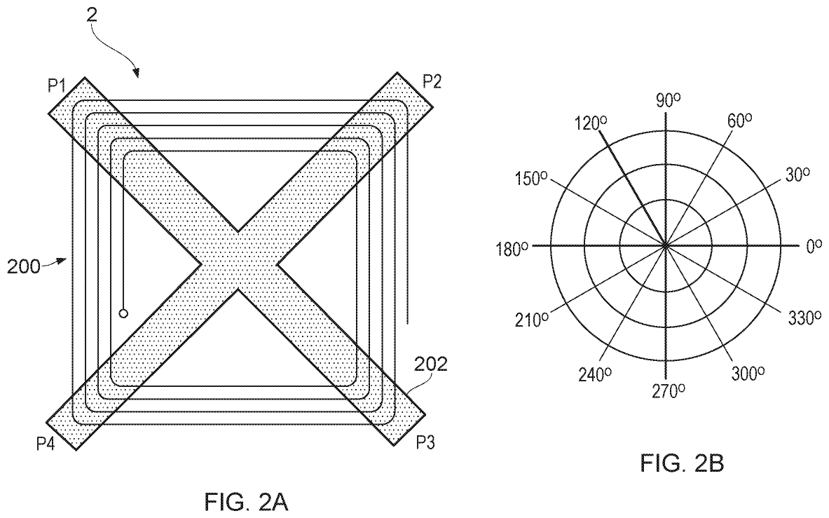

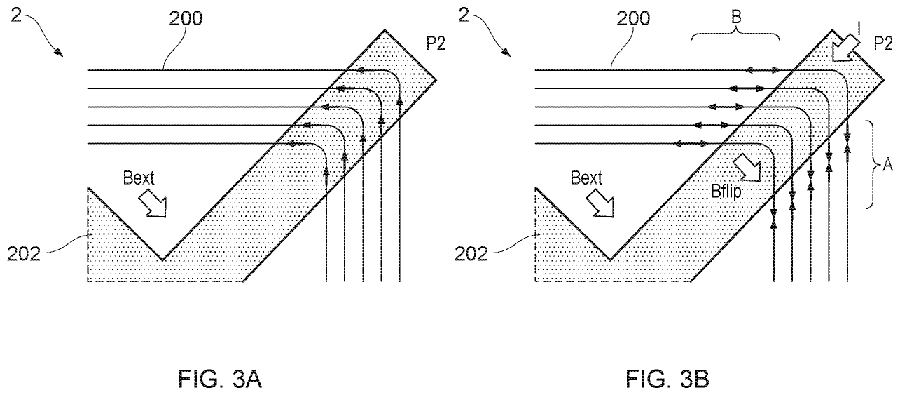

An example of the initialisation device and its method of use will be now be described with reference to FIGS. 2A-2B and 3A-3B. FIG. 2A illustrates a multi-turn sensor system 2 comprising a MT sensor 200 and initialisation device 202. As described with reference to FIG. 1, the MT sensor 200 is in the form of a magnetoresistive track that is physically laid out in an open loop spiral configuration. The initialisation device 202 is an “X” or “cross” shaped conductor that is located in close proximity the MT sensor 200 such that the arms of the initialisation device 202 having terminals P1-P4 are positioned over (or below) the corners of the spiral. Typically, the initialisation device 202 is placed approximately 2-8 micrometres above or below the MT sensor 200 and is made of a non-ferromagnetic material such as Gold, Copper, Aluminium or an alloy comprising Aluminium and Copper. Whilst the initialisation device 202 is shown as an X-shaped portion of material having a planar upper surface, it will be appreciated that the initialisation device 202 may be in any suitable form, for example, a wire or the like, provided it only extends over the corner regions of the MT sensor 200.

The terminals P1-P4 may be electrically connected in any suitable way, for example, with terminals P1, P3 and P4 being connected to ground and P2 being connected to voltage supply. By connecting only one terminal to the voltage supply, a lower resistance will be generated, and thus a larger current can be driven into the initialisation device 202 with a lower voltage.

In use, a current is applied to one of these terminals P1-P4 so as to generate a magnetic field that is strong enough to generate domain pairs of domain walls in the corner regions of the sensor spiral. Typically, a current pulse is applied to generate a magnetic field strength in the range of 20 mT to 40 mT.

The direction in which current is applied to the conductor 202 will depend on the orientation of the external magnetic field of the system in which the sensor is installed, for example, the magnetic field generated by a magnet mounted on a rotating shaft. With reference to the polar coordinate system shown in FIG. 2B, Table 1 below provides the direction that the current has to be applied to completely fill the MT sensor spiral with domain walls, depending on the direction of the external magnetic field, Bₑₓₜ.

TABLE 1

| Magnetic Field Angle of Bₑₓₜ | Current Direction |
|---|---|
| 0°-90° | P1 → P3 |
| 90°-180° | P4 → P2 |
| 180°-270° | P3 → P1 |
| 270°-360° | P2 → P4 |

FIGS. 3A and 3B illustrate the method of initialisation in more detail. FIG. 3A illustrates one corner of the MT sensor 200 prior to initialisation. All of the spiral tracks having no domain wall are initialised in the direction shown by the arrows. The MT sensor system 2 has been installed in a mechanical system to be monitored and the mechanical system has been driving to an end point, either zero turns or its maximum number of turns. An external magnetic field, Bₑₓₜ, is being applied, typically by a permanent magnet connected to the mechanical system. If this is the magnetic field that the MT sensor 200 will be measuring, the field strength of Bₑₓₜ will be somewhere within the operating window of the MT sensor 200, and is therefore not strong enough to nucleate domain walls itself. Using an angle sensor the direction of the external magnetic field, which in this example is an angle of approximately 305° according to the coordinate system of FIG. 2B. Therefore, as shown in Table 1 above, the current must be applied from arm P2 to arm P4 of the initialisation device 202.

As illustrated by FIG. 3B, the application of a current to the initialisation device 202 at P2 generates a magnetic field, B_{flip}. This magnetic field is strong enough to generate pairs of domain walls in each track of the corner regions corresponding to arms P2 and P4, which will then be driven by the external magnetic field, Bₑₓₜ, so as to propagate along the tracks in opposite directions towards the other two corners. As such, the domain walls illustrated by the head to head arrows, denoted as A, will propagate towards the bottom right corner corresponding to arm P3, whilst the domain walls illustrated by the tail to tail arrows, denoted as B, will propagate towards the top left corner corresponding to arm P1, thereby magnetising each track as it passes through.

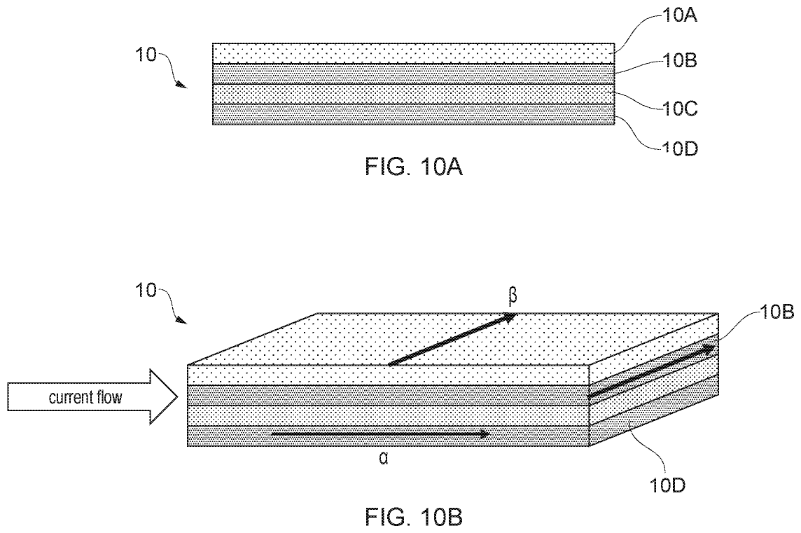

In a GMR based sensor, the sensor elements are formed as a GMR spinvalve stack, such as that shown in FIGS. 10A-B. The stack 10 typically comprises an antiferromagnetic layer 10A, a ferromagnetic “pinned” layer 10B, a non-magnetic spacer 10C and a ferromagnetic “free” layer 10D. The antiferromagnetic layer 10A is pinning the pinned layer 10B, meaning that the magnetisation of the pinned layer 10B is substantially fixed and will not substantively change direction when an external magnetic field is applied. The free layer 10D, on the other hand, does change its magnetisation and will ideally follow the direction of an external magnetic field. The resistance change of the stack 10 as a result of the free layer 10D changing magnetisation is as follows:

R=R₀−ΔR cos(α−β) [1]

Where α is the magnetisation direction of the free layer 10d, β is the magnetisation direction of the pinned layer 10B, R₀ is the base resistance and ΔR is the maximum resistance change.

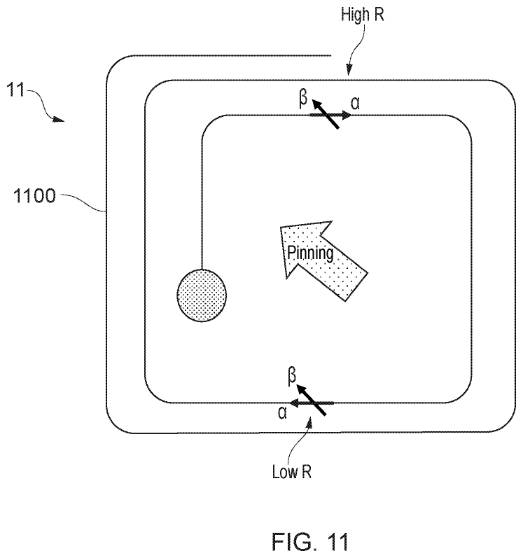

Typically, the pinning is at an angle of 45°, as shown in FIG. 11, which is generally a lot easier to manufacture instead of giving each element its own magnetisation direction. FIG. 11 shows an example multi-turn sensor 11 comprising a magnetoresistive track 1100. Due to this 45° pinning, a full output signal is not achieved when α−β=0° or α−β=180°. However, a clear high and low resistance signal is achieved with α−β=45° or α−β=225°. For example, a first magnetoresistive track (denoted “High R”) has a pinned layer with a magnetisation direction of 45° and a free layer with a magnetisation direction of 270°, which produces a clear high resistance signal. A further magnetoresistive track (denoted “Low R”) again has a pinned layer with a magnetisation direction of 45°, but a free layer with a magnetisation direction of 90°, which produces a clear low resistance signal.

Therefore, returning to the example of FIGS. 3A-B, the domain walls will propagate along the track 200, such that the “free” layer of each magnetoresistive element is magnetised in a direction towards that of the pinned layer (corresponding to a low resistance state, as shown in FIG. 11) or in a direction away from that of the pinned layer (corresponding to a high resistance state, as shown in FIG. 11).

If however the current was applied in this direction, and the external magnet field was pointing the opposite direction for example, the domain walls would propagate towards each other and annihilate immediately after nucleation. Likewise, if the current was applied in the opposite direction, with the external magnetic field pointing in the direction shown, this would again result in domain wall annihilation. Therefore, it is important to measure the direction of the external magnetic field first in order to correctly determine the direction in which the current should be applied to the initialisation device 202.

The initialisation device 202 therefore provides a quick and energy efficient way of initialising the MT sensor 200. Only a short pulse of current needs to be applied to nucleate the domain walls, typically no longer than a microsecond, after which the external magnetic field propagates the domain walls around spiral to magnetically align the sensor elements. As such, very little energy is needed to perform the initialisation.

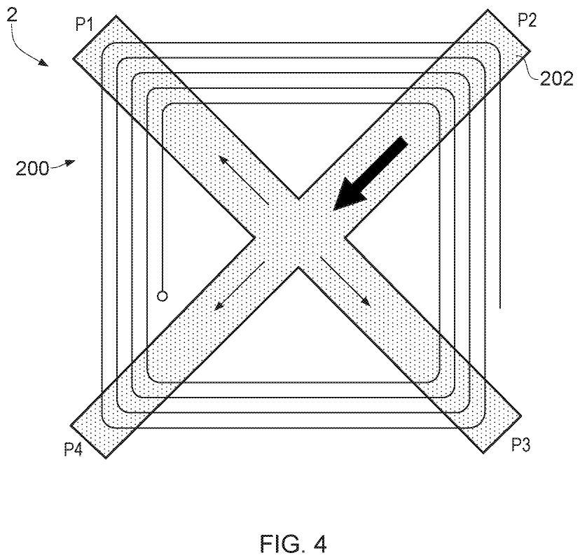

As an alternative, the current may be applied to one terminal of the initialisation device 202 and spread between the other three terminals. For example, as shown in FIG. 4, the current may be applied to terminal P2 and divided between terminals P1, P3 and P4. In such cases, the terminal at which the current should be applied is again based on the external magnetic field direction, as shown in Table 2 below.

TABLE 2

| Magnetic Field Angle of Bₑₓₜ | Current Direction |
|---|---|
| 0°-90° | P1 → P2, P3, P4 |
| 90°-180° | P4 → P1, P2, P3 |
| 180°-270° | P3 → P1, P2, P4 |
| 270°-360° | P2 → P1, P3, P4 |

As before, this will nucleate domain walls in the corner corresponding to the terminal to which the current is being applied, with the external magnetic field propagating the nucleated domain walls around the spiral.

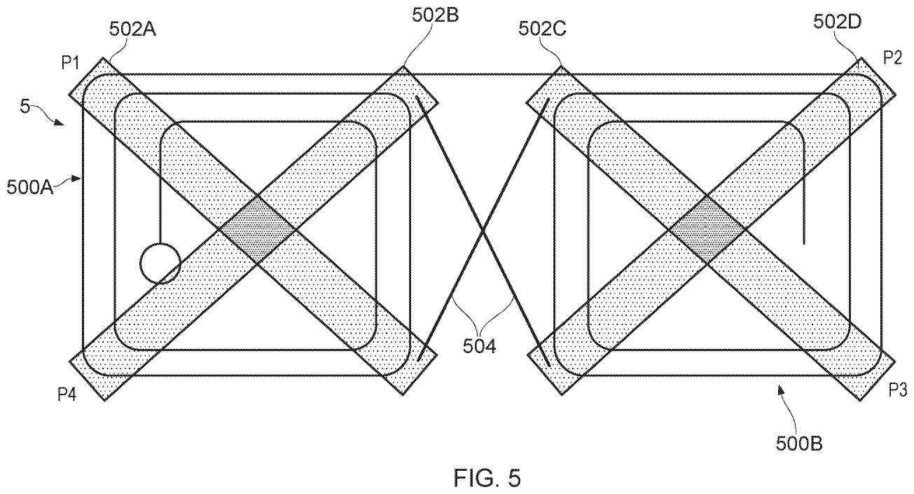

FIG. 5 illustrates a further example of a multi-turn sensor system 5, wherein the MT sensor has been split into two connected spirals 500A and 500B, for example, to save space by minimising the diameter and thus the length of magnetoresistive track required, the initialisation device will be provided by four strips of conducting material 502A-D arranged to form two connected “X” shapes, with the terminals P1-P4 being provided at the outermost corners of the sensor track. Electrical connection wires 504 are then provided to connect the two conductors 502A and 502B such that opposing terminals P1 and P3 are connected and opposing terminals P2 and P4 are connected. In this arrangement, the conductors of each “X” must not be connected at the centre to ensure the current path between opposing terminals is not disrupted. To determine which terminal a current pulse should be applied to, the rules set out in Table 1 above are applied.

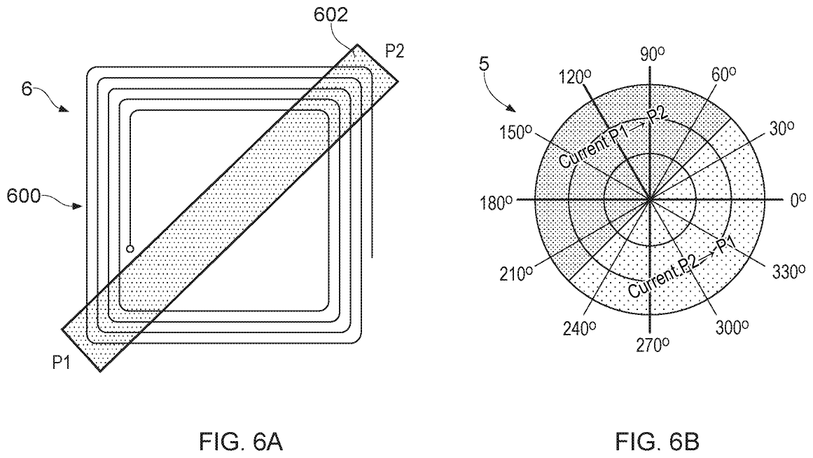

FIG. 6A illustrates a simplified magnetic sensor system 6, wherein the initialisation device 602 is provided as a single strip of conducting material arranged over two opposing corners of the MT sensor spiral 600. FIG. 6B illustrates the required current direction according to the external field angle. Here it can be seen that for angles of 45° to 235°, the current should be applied at terminal P1 towards terminal P2, and for angles of 0° to 45° and 235° to 360°, the current should be applied at terminal P2 towards terminal P1. As before, the applied current will generate a magnetic field, B_{flip}, which will nucleate domain walls in the spiral corners below the terminal to which the current is applied, with the external magnetic field propagating the nucleated domain walls around the spiral to initialise the sensor 600.

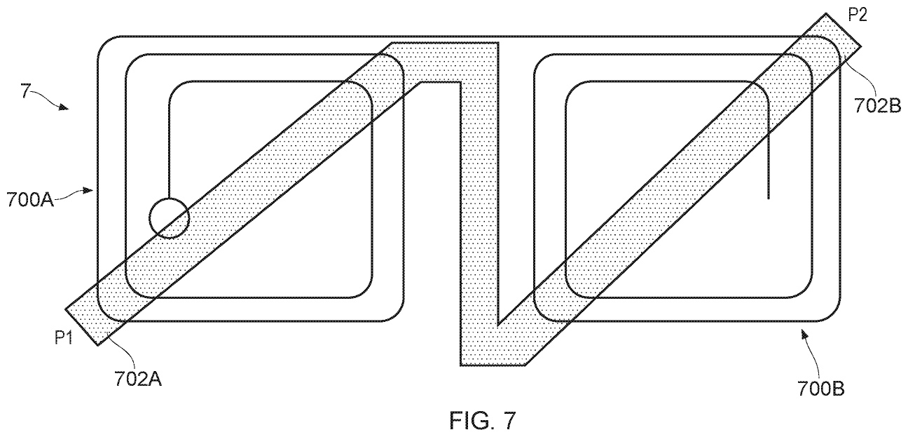

This can be extended to a double spiral MT sensor system 7, as shown by FIG. 7, wherein the initialisation device is in the form of a single strip of conducting material that has been shaped to form two arms 702A and 702B that extend over the same two opposing corners of the two spirals 700A and 700B.

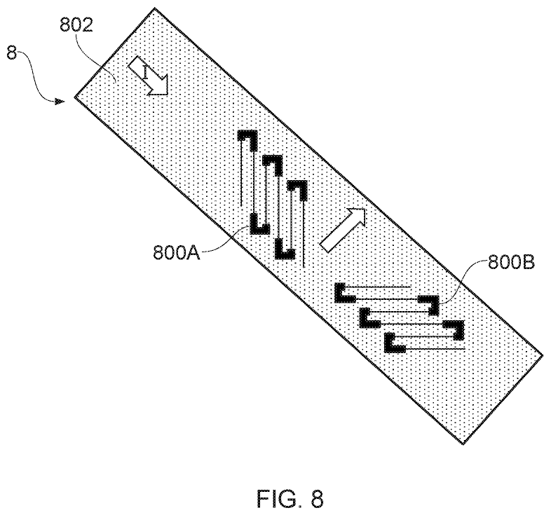

In any of the above examples, reference resistors having a known magnetisation direction may be used to compare to the magnetoresistive elements of the sensor spirals. These reference resistors will also need to be initialised, and hence the initialisation device described above can be used in substantially the same way, as illustrated by FIG. 8. FIG. 8 shows a reference system 8 comprising two portions of reference resistors 800A and 800B, wherein the resistors of one portion 800A have a vertical orientation and the resistors of the other portion 800B have a horizontal orientation. An initialisation device 802 in the form of a strip of conductive material is placed above or below the reference resistors 800A-B. A current pulse can then be applied to the initialisation device 802 to thereby magnetise all of the reference resistors in one direction. In this respect, it does not matter which direction the reference resistors are magnetised, as long as it is known whether they are in a high or low resistance state.

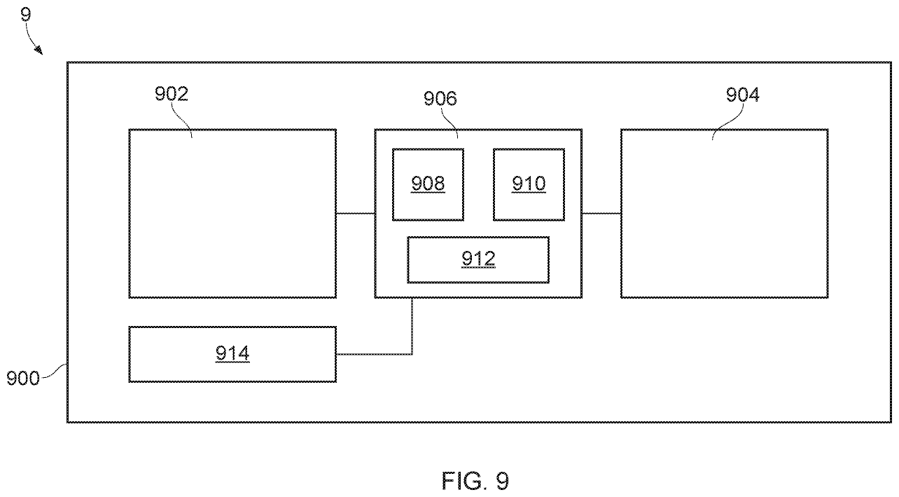

FIG. 9 illustrates a schematic block diagram of an example magnetic sensing device 9 that includes a multi-turn (MT) sensor system 902 and an angle sensor 904 provided in a single semiconductor package. The MT sensor system 902 comprises an MT sensor and an initialisation device, such as those described with reference to FIGS. 1 to 7. The angle sensor 904 may be any suitable angle sensor, for example, an anisotropic magnetoresistive (AMR), giant magnetoresistive (GMR) or tunnel magnetoresistive (TMR) based sensor, a Hall sensor or an inductive sensor. However, for the purposes of determining the magnetic field angle in order to determine the direction in which the current should be applied to the initialisation device, an angle sensor 904 capable of providing 360° angle information. For angle sensors 904 having a resolution of 180°, such as an AMR angle sensor, a quadrant detector will also be required to determine whether the angle information relates to the first half of a full rotation, i.e. 0° to 180°, or the second half, i.e. 180° to 360°.

The sensing device 9 may also comprise a reference system 914 such as that described with reference to FIG. 8.

The sensing device 9 also comprises a processing circuit 906, and an integrated circuit 900 on which the MT sensor system 902, the angle sensor 904 and processing circuit 906 are disposed. The processing circuit 906 receives signals from the MT sensor of the MT sensor system 902 and processes the received signals to determine that the turn count using a turn count decoder 908, which will output a turn count representative of the number of turns of an external magnetic field (not shown) rotating in the vicinity of the MT sensor system 902, for example, a magnetic field generated by a magnet mounted on a rotating shaft. Similarly, the processing circuit 906 may also receive signals from the angle sensor 904 and process the received signals using an angle decoder 910 to output an angular position of the external magnetic field.

The angular position may then be output to a current decoder 912, which determines the direction in which the current should be applied to the initialisation device and then uses this determination to control a power source (not shown) to apply the current pulse.

The angle sensor 904 is being used in embodiments of the present disclosure to measure the direction of the external magnetic field in order to determine how to apply the current to the initialisation device, and therefore, in its simplest form, the angle sensor 904 may be a quadrant detector since it is only necessary to know which 90° quadrant the external magnetic field is in. However, it will be appreciated that after initialisation has occurred, the angle sensor 904 may also be used for monitoring the angular position of the mechanical system, in which case, an angle sensor of higher resolution will be required.

It will also be appreciated that the signals from the MT sensor system 902 and angle sensor 904 may be processed by some other external processing means. For example, a separate computing device (not shown) having a processor and a computer readable storage medium for storing instructions that, when executed by the processor, cause the processor to determine the orientation of the magnetic field based on the signals received from the angle sensor 904 via a wired or wireless connection, and subsequently determine the direction in which current should be applied to the initialization device and control a power source to apply the current accordingly.

Various modifications, whether by way of addition, deletion and/or substitution, may be made to all of the above described embodiments to provide further embodiments, any and/or all of which are intended to be encompassed by the appended claims.

For example, whilst the examples described above show open loop multi-turn sensors, it will be appreciated that any of the initialisation devices according to embodiments of the disclosure may be used with a closed loop multi-turn sensor in the same way.

Whilst the examples described with reference to FIGS. 2-7 show the initialisation device placed a small distance above the multi-turn sensor, it will be appreciated that the initialisation device may alternatively be placed a small distance below the multi-turn sensor. In some cases, the initialisation device may comprise a first conductor placed above the multi-turn sensor and a second conductor placed below the multi-turn sensor. For example, the example of FIG. 2A may be modified so that a first conductor between terminals P1 and P3 is placed above the multi-turn sensor 200, and a second conductor between terminals P2 and P4 are placed below the multi-turn sensor 200.

In the above examples, the direction of the external magnetic field is measured to determine which terminals of the conductor should be applied to ensure that the nucleated domain walls propagate around the magnetoresistive tracks of the multi-turn sensor. However, instead of measuring the direction of the external magnetic field, a current may be sequentially applied to each terminal in all possible directions. Taking the conductor 202 shown in FIG. 2A as an example, the current may be sequentially applied from P1 to P3, P2 to P4, P3 to P1, and finally P4 to P2. With each current pulse applied, pairs of domain walls will be nucleated at the relevant corner regions, as described above, which will then either propagate towards or away from each other depending on the direction of the external magnetic field. In this way, one of the current pulses in the sequence will result in the magnetoresistive tracks being magnetised into the initialised state as described above. For example, as outlined in Table 1 above, if the external magnetic field has a magnetic field angle of 225° when the sequence of pulses are applied, the initialisation will occur when the current is applied between P3 and P1. Similarly, in the example of FIG. 6A, the current may be applied in sequence in both directions between P1 and P2, wherein the initialisation will occur when the current is applied in one of those directions depending on the direction of the external magnetic field at that time.

1. A device for initialising a magnetic multi-turn sensor, the multi-turn sensor having a plurality of magnetoresistive sensing elements connected in series and arranged in at least one spiral configuration having a plurality of corner regions, the device comprising:
a conductor arranged to be placed in proximity to the multi-turn sensor, wherein the conductor is configured to generate a magnetic field when a sequence of current pulses is applied to the conductor, and wherein each current pulse is applied to a different part of the conductor to thereby generate pairs of domain walls in the magnetoresistive elements defining at least one corner region of the at least one spiral.

2. The device according to claim 1, wherein the sequence of current pulses is applied to different parts of the conductor so that pairs of domain walls are nucleated in plurality of corner regions.

3. The device according to claim 1, wherein the conductor extends from a first corner region of the at least one spiral to a second corner region of the at least one spiral.

4. The device according to claim 3, wherein the first and second corner regions are opposing corner regions, and wherein the sequence of current pulses is applied between the first and second corner regions in both directions.

5. The device according to claim 3, wherein the conductor further extends from a third corner region of the at least one spiral to a fourth corner region of the at least one spiral.

6. The device according to claim 5, wherein the third and fourth corner regions are opposing corner regions, and wherein the sequence of current pulses is applied between each pair of opposing corner regions in both directions.

7. The device according to claim 1, wherein the conductor is cross-shaped.

8. The device according to claim 1, wherein the conductor comprises a non-ferromagnetic material.

9. The device according to claim 8, wherein the non-ferromagnetic material comprises one of: Gold, Copper, Aluminium and an alloy comprising Aluminium and Copper.

10. A method of initialising a magnetic multi-turn sensor, the multi-turn sensor having a plurality of magnetoresistive sensing elements connected in series and arranged in at least one spiral configuration having a plurality of corner regions, the method comprising:
applying a sequence of current pulses to a conductor placed in proximity to the multi-turn sensor, wherein each current pulse is applied to a different part of the conductor such that a magnetic field is generated by the conductor to thereby generate pairs of domain walls in the magnetoresistive elements defining at least one corner region of the at least one spiral.

11. The method according to claim 10, wherein applying the sequence of current pulses to different parts of the conductor results in pairs of domain walls being nucleated in a plurality of corner regions.

12. The method according to claim 10, wherein the conductor extends from a first corner region of the at least one spiral to a second corner region of the at least one spiral.

13. The method according to claim 12, wherein the first and second corner regions are opposing corner regions, the method further comprising applying the sequence of current pulses between the first and second corner regions in both directions.

14. The method according to claim 12, wherein the conductor further extends between a third corner region and a fourth opposing corner region of the at least one spiral.

15. The method according to claim 14, wherein the third and fourth corner regions are opposing corner regions, the method further comprising applying the sequence of current pulses between each pair of opposing corner regions in both directions.

16. A magnetic sensing system, comprising:
a multi-turn sensor having a plurality of magnetoresistive sensing elements connected in series and arranged in at least one spiral configuration having a plurality of corner regions;
an initialisation device comprising a conductor arranged to be placed in proximity to the multi-turn sensor, wherein the conductor is configured to generate a magnetic field when a sequence of current pulses is applied to the conductor, and wherein each current pulse is applied to a different part of the conductor to thereby generate pairs of domain walls in the magnetoresistive elements defining at least one corner region of the at least one spiral.

17. The system according to claim 16, wherein the sequence of current pulses is applied to different parts of the conductor so that pairs of domain walls are nucleated in a plurality of corner regions.

18. The system according to claim 16, wherein the conductor extends from a first corner region of the at least one spiral to a second corner region of the at least one spiral, wherein the first and second corner regions are opposing corner regions, and wherein the sequence of current pulses is applied between the first and second corner regions in both directions.

19. The system according to claim 18, wherein the conductor further extends from a third corner region of the at least one spiral to a fourth corner region of the at least one spiral, wherein the third and fourth corner regions are opposing corner regions, and wherein the sequence of current pulses is applied between each pair of opposing corner regions in both directions.

20. The system according to claim 16, wherein the plurality of magnetoresistive sensing elements are arranged as two connected spirals, the initialisation device being arranged such that the conductor is located in proximity to at least two opposing corner regions of each spiral.
